(19) United States
(12) Patent Application Publication
(10) Pub. No.: US 2026/0107519 A1
(43) Pub. Date: Apr. 16, 2026

(54) TRANSISTOR CHANNEL COMPRESSION FOR SEMICONDUCTOR DEVICES

(71) Applicant: Micron Technology, Inc., Boise, ID (US)

(72) Inventors: Yong Seung Kim, Boise, ID (US); Ronald A. Weimer, Boise, ID (US); Huajie Chen, Boise, ID (US); Chandra S. Tiwari, Boise, ID (US)

(21) Appl. No.: 19/354,160

(22) Filed: Oct. 9, 2025

Related U.S. Application Data
(60) Provisional application No. 63/707,635, filed on Oct. 15, 2024.

(51) Int. Cl. H10D 30/69; H10D 62/00; H10D 62/13; H10D 62/822

(52) U.S. Cl. CPC H10D 30/797; H10D 62/021; H10D 62/151; H10D 62/822

(57) ABSTRACT

Methods, systems, and devices for transistor channel compression for semiconductor devices are described. One or more trenches in a substrate may be filled with layers of silicon germanium (SiGe), where each layer may be associated with different concentrations of germanium. A direction of the one or more trenches relative to the substrate may cause a floor of the one or more trenches may be associated with a same crystalline orientation as or a different crystalline orientation from the sidewalls of the one or more trenches, which may affect an epitaxial formation of the layers of SiGe in different directions. The layers of SiGe may increase a strain on a portion of the substrate between the trenches. Additionally, one or more of precursors, temperatures, and pressures may be tailored in one or more processes for forming the layers of SiGe to provide the increased compressive stress.

### CROSS REFERENCE

The present Application for Patent claims priority to U.S. Patent Application No. 63/707,635 by Kim et al., entitled “TRANSISTOR CHANNEL COMPRESSION FOR SEMICONDUCTOR DEVICES,” filed October 15, 2024, which is assigned to the assignee hereof, and which is expressly incorporated by reference in its entirety herein.

### TECHNICAL FIELD

The following relates to one or more semiconductor systems, including transistor channel compression for semiconductor devices.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports transistor channel compression for semiconductor devices in accordance with examples as disclosed herein.

FIGS. 2A through 2E show aspects of semiconductor components that support transistor channel compression for semiconductor devices in accordance with examples as disclosed herein.

FIGS. 3A through 3E show aspects of semiconductor components that support transistor channel compression for semiconductor devices in accordance with examples as disclosed herein.

FIGS. 4 and 5 show flowcharts illustrating methods that support transistor channel compression for semiconductor devices in accordance with examples as disclosed herein.

### DETAILED DESCRIPTION

Some semiconductor components (e.g., semiconductor wafers, semiconductor dies, semiconductor systems) may include material portions embedded in a substrate to increase transistor performance (e.g., to increase hole carrier mobility associated with transistor channels). For example, a semiconductor component may include a substrate (e.g., a crystalline semiconductor substrate, a silicon substrate) with silicon germanium (SiGe) portions formed in trenches associated with transistor terminals. The SiGe may be formed (e.g., deposited) in the trenches using various techniques (e.g., chemical vapor deposition (CVD), epitaxial formation), such that a crystalline structure (e.g., one or more lattice orientations) of the substrate is continued into the SiGe portions. The presence of germanium may cause a lattice constant of the SiGe portions to be different (e.g., along one or more lattice orientations) than a lattice constant of the substrate, which may cause compressive strain in portions of the substrate between the SiGe portions. Compressive strain may improve hole carrier mobility in the substrate, and may be implemented to improve the performance of a resultant transistor (e.g., when compressive strain is implemented in channel portions of transistors, such as with a compressive strain aligned along a direction transistor channels). An increased concentration of germanium in the SiGe portions may be associated with more compressive strain in the substrate, but may be associated with fabrication challenges.

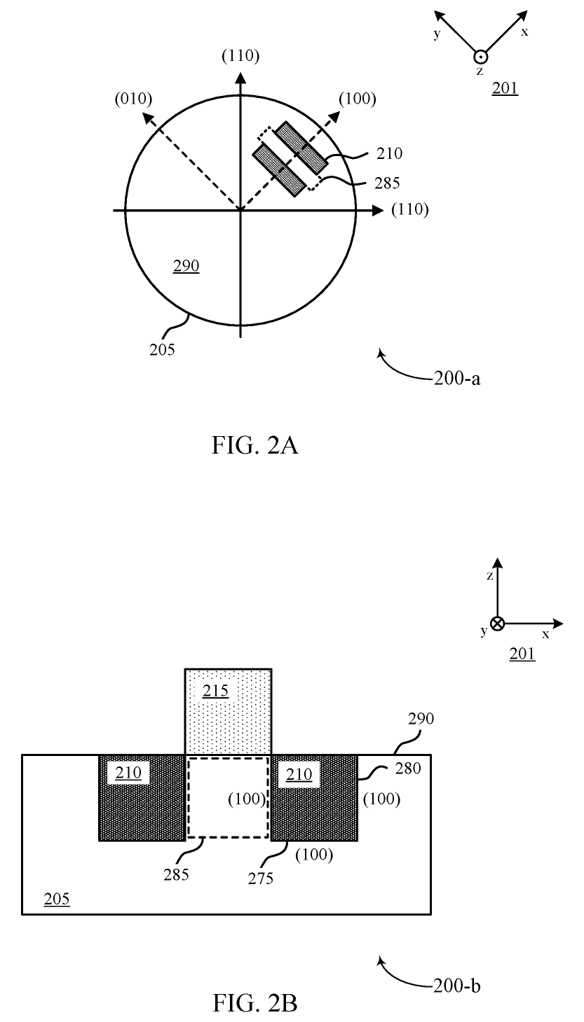

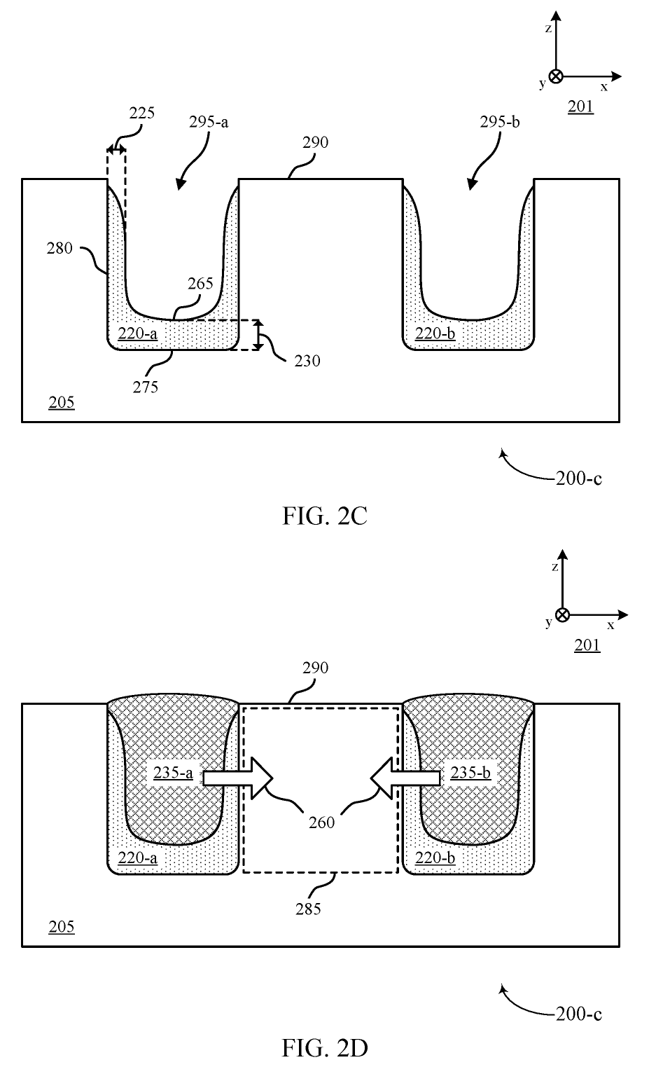

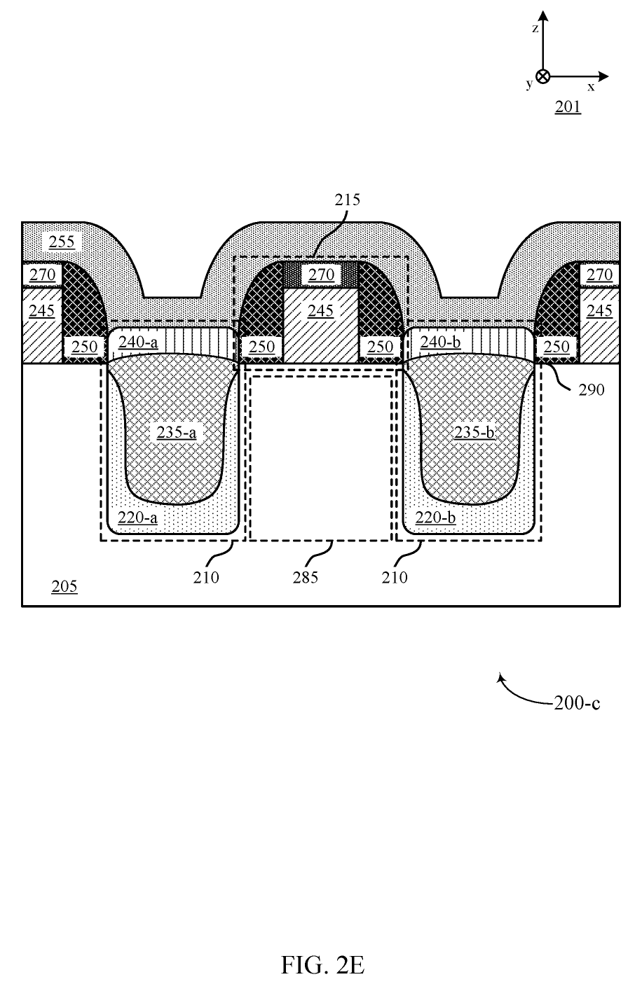

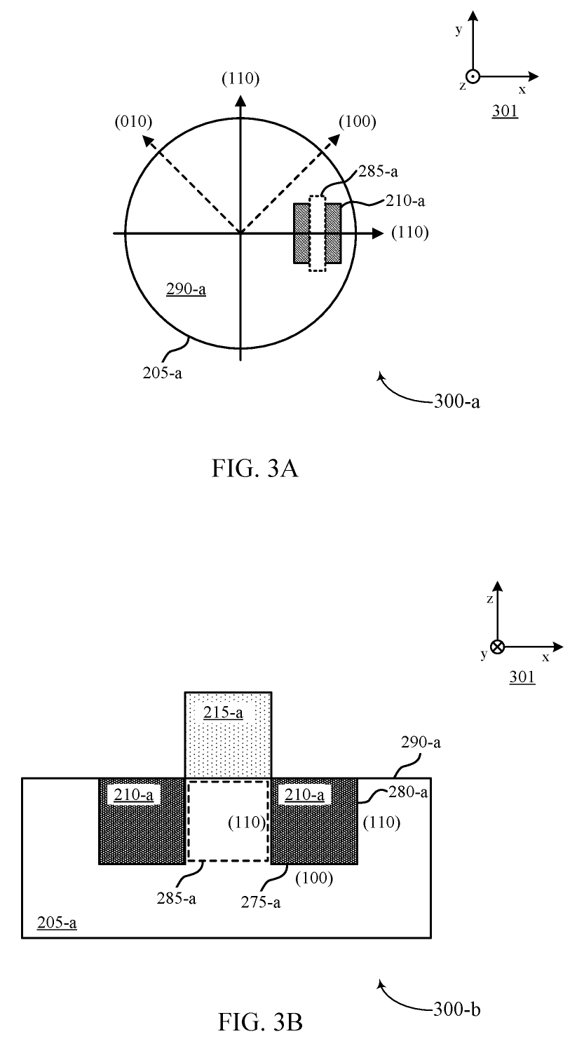

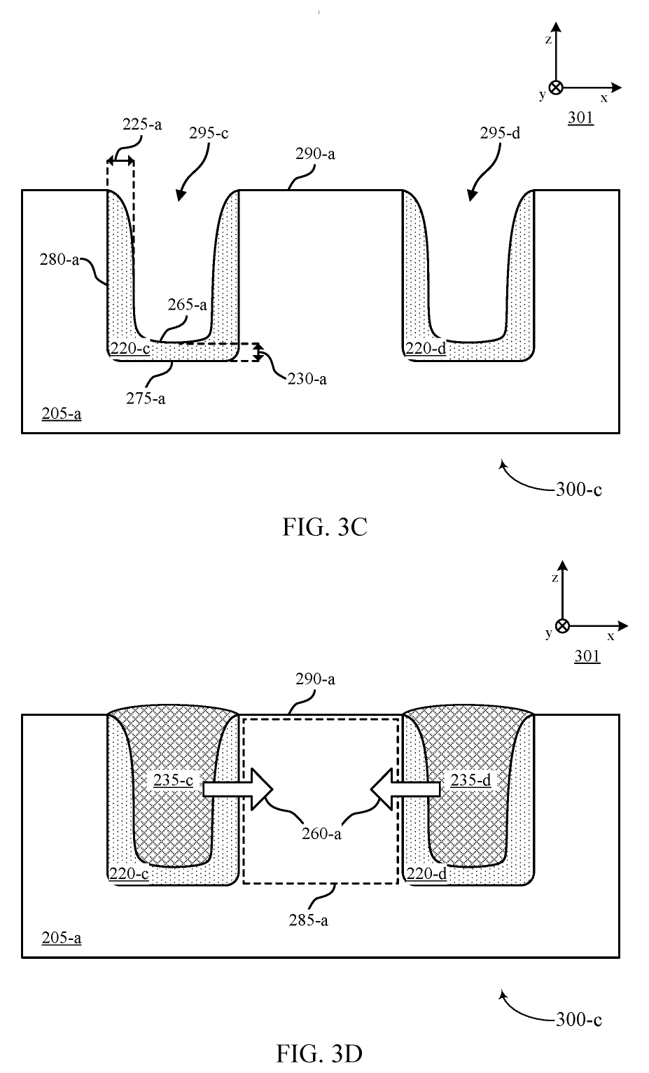

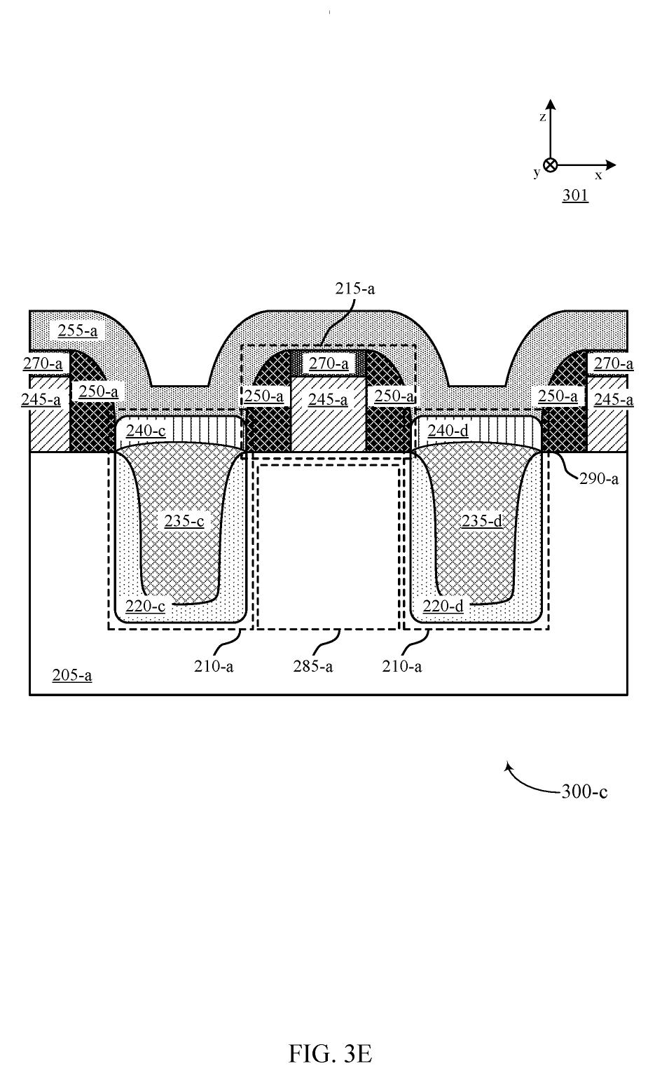

In accordance with techniques described herein, a semiconductor component may be formed with embedded SiGe(eSiGe) that provides relatively higher compressive stress in transistor channels, and may thus experience increase performance gains. For example, one or more trenches in a substrate may be filled with layers of SiGe, where the layers of SiGe may be associated with progressively higher concentrations of germanium. In some cases, one or more trenches may be formed in a first direction relative to the substrate (e.g., 45 degrees, as described with respect to FIGS. 2A through 2E) such that a floor of the trenches may be associated with a same crystalline orientation as the sidewalls of the trenches. Additionally, or alternatively, one or more trenches may be formed in a different direction relative to the substrate (e.g., 0 degrees, as described with respect to FIGS. 3A to 3E) such that the floor of the trenches may be associated with a different crystalline orientation than the sidewalls of the one or more trenches. In some aspects, the crystalline orientations of the floor and sidewalls of the one or more trenches may affect an epitaxial formation (e.g., crystalline growth rates) of the layers of SiGe in different directions. Additionally, one or more of precursors, temperatures, and pressures may be tailored in processes for forming the layers of SiGe to provide increased compressive stress, and thus increase performance gain.

In addition to applicability in memory systems as described herein, techniques for transistor channel compression for semiconductor devices may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of semiconductor devices by increasing compressive stress in transistor channels, which may reduce latency, reduce power consumption, and/or increase processing or data access throughput, among other benefits.

Features of the disclosure are illustrated and described in the context of systems and architectures. Features of the disclosure are further illustrated and described in the context of formation diagrams and flowcharts.

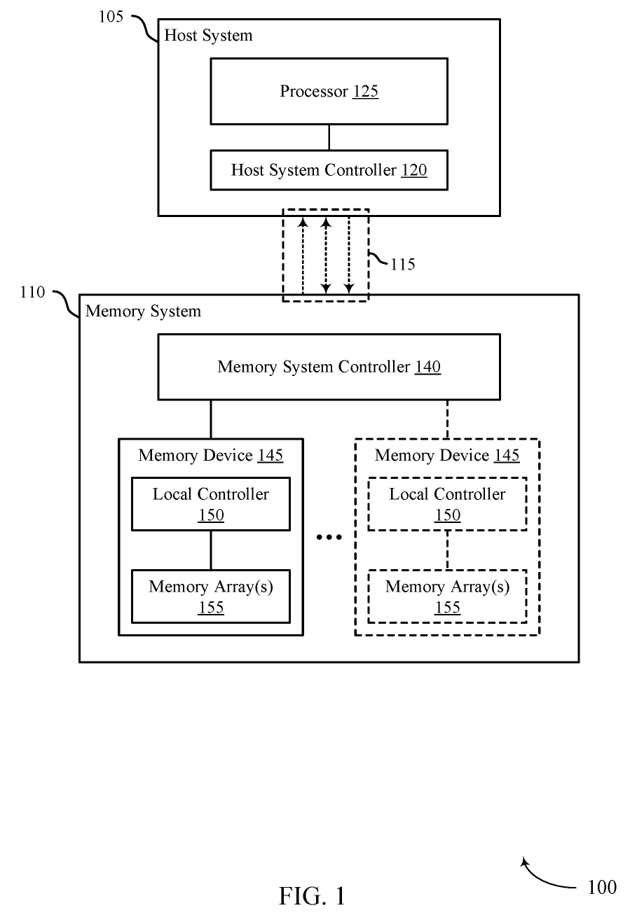

FIG. 1 illustrates an example of a system 100 that supports transistor channel compression for semiconductor devices in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

Some semiconductor components (e.g., semiconductor wafers, semiconductor dies, semiconductor systems, including but not limited to memory cells, switches, transistors, logic circuitry, processing circuitry, or other components in the system 100) may include material portions embedded in a substrate to increase transistor performance (e.g., to increase hole carrier mobility associated with transistor channels). For example, a semiconductor component may include a substrate with SiGe portions formed in trenches associated with transistor terminals. The SiGe may be formed in the trenches using various techniques, such that a crystalline structure of the substrate is continued into the SiGe portions. The presence of germanium may cause a lattice constant of the SiGe portions to be different than a lattice constant of the substrate, which may cause compressive strain in portions of the substrate between the SiGe portions. Compressive strain may improve hole carrier mobility in the substrate, and may be implemented to improve the performance of a resultant transistor (e.g., when compressive strain is implemented in channel portions of transistors, such as with a compressive strain aligned along a direction transistor channels). An increased concentration of germanium in the SiGe portions may be associated with more compressive strain in the substrate, but may be associated with fabrication challenges.

In accordance with techniques described herein, a semiconductor component that implements aspects of a system 100 may be formed with increased compressive stress due to eSiGe, and may thus experience increase performance gains. For example, one or more trenches in a substrate may be filled with layers of SiGe, where the layers of SiGe may be associated with progressively higher concentrations of germanium. In some cases, one or more trenches may be formed along a first direction relative to the substrate, such that a floor of the trenches may be associated with a same crystalline orientation as the sidewalls of the trenches. Additionally, or alternatively, one or more trenches may be formed in along a second direction relative to the substrate such that a floor of the trenches may be associated with a different crystalline orientation than the sidewalls of the trenches. In some aspects, the crystalline orientations of the floor and sidewalls of the one or more trenches may affect an epitaxial formation of the layers of SiGe in different directions. Additionally, one or more of precursors, temperatures, and pressures may be tailored in one or more processes for forming layers of SiGe to provide increased compressive stress, and thus a higher performance gain.

FIGS. 2A through 2E show aspects of semiconductor components 200 (e.g., semiconductor components 200-a through 200-c) that support transistor channel compression for semiconductor devices in accordance with examples as disclosed herein. A semiconductor component 200 may be used to implement one or more components of a system 100 (e.g., as a semiconductor die, as a set of multiple semiconductor dies). For example, one or more semiconductor components 200 may be used to implement aspects of a host system 105 or portion thereof (e.g., a processor 125, a host system controller 120), or a memory system 110 or portion thereof (e.g., a memory system controller 140, a memory device 145), or a combination of aspects of a host system 105 and a memory system 110, among other implementations. Aspects of the semiconductor components 200 may be described with reference to an x-direction, a y-direction, and a z-direction of the illustrated coordinate system 201.

In various implementations, or at various stages of manufacturing, a semiconductor component 200 may refer to aspects of a semiconductor wafer, a semiconductor die, or a set of multiple (e.g., stacked, coupled) semiconductor dies, among other implementations. A semiconductor component 200 may include a substrate 205 (e.g., a semiconductor substrate, a crystalline semiconductor, crystalline silicon), upon which one or more circuit elements (e.g., transistors, capacitors, access lines) may be formed. For example, a substrate 205 may include a first semiconductor material that is a basis for forming transistors, each of which may include a respective channel portion (e.g., one or more doped semiconductor materials) and a respective gate portion operable to modulate a conductivity of the respective channel portion. FIG. 2A may illustrate a top view of a semiconductor component 200-a (e.g., in wafer form, along the z-direction), and FIG. 2B may illustrate a cross-sectional view of a portion of a semiconductor component 200-b (e.g., in an xz-plane), both of which may illustrate features related to transistors of the respective semiconductor component 200 (e.g., terminal portions 210, a substrate portion 285 as a portion of the substrate 205, and a gate portion 215 operable to modulate a conductivity between terminal portions 210 and through the substrate portion 285). FIGS. 2C through 2E may illustrate steps in a process of forming transistors having terminal portions 210 (e.g., formed in trenches 295), substrate portions 285, and gate portions 215, among other aspects of a semiconductor component 200-c. Other circuit elements may be present in a semiconductor component 200 to support a given implementation, but are omitted from the illustrations.

In accordance with examples as disclosed herein, transistors of a semiconductor component 200 may include terminal portions 210 that are formed in trenches 295 of the substrate 205, which may support forming substrate portions 285 with a retained compressive stress (e.g., along a direction of a transistor channel). For example, to support at least some transistors (e.g., substrate-based transistors, complementary metal-oxide semiconductor (CMOS) transistors, P-type metal-oxide semiconductor (PMOS) transistors), one or more semiconductor materials (e.g., second semiconductor material(s), different than the material of the substrate 205), such as one or more formulations of SiGe, may be formed in trenches 295 on either side of substrate portion(s) 285 to form terminal portions 210, where such terminal portions 210 may induce a compressive stress that enhances hole carrier mobility in the substrate portion(s) 285. The enhanced hole carrier mobility may significantly improve transistor performance, such as enhancing drive current, improving channel conductivity, among other benefits.

In some examples, a material of terminal portions 210, such as SiGe, may be associated with a higher lattice constant than a material of the substrate 205, such as silicon. For example, atoms of silicon and germanium in a SiGe lattice may preferentially have a greater separation from each other than the atoms of silicon in a silicon lattice, which may be a function of the concentration of germanium in the SiGe lattice. In some examples, when SiGe is formed in a trench 295 (e.g., on a sidewall 280 of a trench 295, on a floor 275 of a trench 295, or both), a crystalline orientation of the surface (e.g., of the substrate 205, of a deposition surface) may be continuous into the SiGe. A continuous crystalline orientation from the substrate 205 into the SiGe of a terminal portion 210 may support the lattice of the SiGe, which may otherwise be in a more-expanded condition, to exert a compressive force on the lattice of the substrate 205, such that the SiGe in the terminal portions 210 on either side of the substrate portion 285 cause a compressive strain 260 (e.g., a strain along a lattice direction, a uniaxial strain, a strain along the x-direction, a strain along a transistor channel direction) on the substrate portion 285 (e.g., on a silicon lattice of the substrate portions 285) due to the higher lattice constant of the SiGe. A relatively higher concentration of germanium in the SiGe may be associated with a relatively higher lattice constant, which may support relatively higher compressive strain 260 imparted to the substrate portions 285. However, a relatively higher concentration of germanium (e.g., and thus an increased lattice constant) may also be associated with greater difficulty for epitaxially forming a SiGe lattice from a silicon lattice.

As shown in FIG. 2A, substrate portions 285 may be configured between terminal portions 210 in a manner that supports transistor channels being aligned along the x-direction (e.g., with a channel direction of one or more transistors being aligned along the x-direction), and the x-direction (e.g., an xz-plane) may be aligned relative to the substrate 205 at an angle between certain orientations of a crystalline lattice of the substrate 205. For example, directions relative to substrate 205 may correspond to different crystalline orientations of the substrate 205 (of a silicon lattice), indicated by three digits in parenthesis or chevron brackets (e.g., (110) or <110>, which may be equivalent representations). In the example of FIG. 2A, one or more directions (e.g., along a substrate 205) may be associated with a (110) crystalline orientation, which may be some angle apart from each other (e.g., 90 degrees, more than 90 degrees, less than 90 degrees). In the illustrated arrangement of FIG. 2A, the x-direction of the coordinate system 201 (e.g., at least some transistor channels) may be aligned along a (100) crystalline orientation, and the y-direction of the coordinate system 201 may be aligned along a (010) crystalline orientation, which may be referred to as a 45-degree orientation (e.g., a 45-degree wafer, a formation orientation with an x-direction or xz-plane oriented with a 45-degree angle relative to a (110) crystalline orientation, a formation orientation for transistor channels oriented with a 45-degree angle relative to a (110) crystalline orientation).

To support the formation of terminal portions 210, the sidewalls 280 and the floor 275 of respective trenches 295 may be configured with respective crystalline orientations that are based on the orientation of the trenches 295 relative to the lattice directions of the substrate 205 (e.g., in accordance with a wafer orientation, specified by degrees from a line along a direction associated with a (110) crystalline orientation of the substrate 205). In some examples, a growth rate and cross sectional profile of epitaxially-formed material(s) of terminal portions 210 may depend on the crystalline orientation of a surface within the trench 295 from which it grows. In the example of semiconductor components 200-a through 200-c, trenches 295 may be oriented on the substrate 205 in accordance with a 45-degree wafer configuration, which may be associated with sidewalls 280 and a floor 275 of respective trenches 295 having a same crystalline orientation (e.g., a (100) crystalline orientation).

FIGS. 2C - 2E illustrate an example of forming a semiconductor component 200-c (e.g., an eSiGe semiconductor component) in accordance with a 45-degree wafer configuration. In the example of semiconductor component 200-c, each terminal portion 210 may include multiple semiconductor layers (e.g., epitaxial layers, three layers). For example, the semiconductor layers may include a first layer 220 (e.g., of a second semiconductor material, a buffer layer, an L1 layer), a second layer 235 (e.g., of a third semiconductor material, a main layer, an L2 layer), and a third layer 240 (e.g., of a fourth semiconductor material, a capping layer, an L3 layer). The semiconductor layers may have different concentrations of germanium, for example. For example, a first concentration of germanium in the first layer 220 may be 20% (e.g., approximately 20%, between 10% and 30%), a second concentration of germanium in the second layer 235 may be 40% (e.g., approximately 40%, between 30% and 50%), and a third concentration of germanium in the third layer 240 may be 0% (e.g., <1% germanium concentration). Each layer may be formed (e.g., deposited, grown), for example, using CVD, which may use one or more chemical vapor precursors in conjunction with one or more other material vapors to deposit the respective semiconductor material in the trenches 295.

As illustrated in FIG. 2C, one or more trenches 295 (e.g., a trench 295-a, a trench 295-b) may be formed below a top surface 290 of the substrate 205. The substrate 205 may be a first semiconductor material, which may include silicon (e.g., a silicon wafer, a silicon substrate), and may include an n-type doping (e.g., at least in substrate portions 285). The trenches 295 may be formed using one or more forming techniques (e.g., chemical etching, other forming techniques). In some examples, trenches 295 may be deeper than they are wide (e.g., having a width of approximately 50 nanometers (nm) and a depth of approximately 60 nm).

A first layer 220-a of SiGe and a first layer 220-b of SiGe may be formed in the trench 295-a and the trench 295-b, respectively. Each first layer 220 of SiGe may line the surfaces of a respective trench 295 below the top surface 290, and may be a second semiconductor material (e.g., SiGe, having a first concentration of germanium). In some cases, the second semiconductor material may have a p-type doping. The first layer 220 may be formed epitaxially from the sidewalls 280 and floors 275 of the trenches 295, which may be supported by a concentration of germanium being less than or equal to a threshold concentration (e.g., below a 30% concentration).

In some examples (not shown in FIG. 2C), a shared crystalline orientation (e.g., (100) orientation) along the sidewalls 280 and floors 275 of the trenches 295 (e.g., based on the 45-degree wafer configuration) may cause the first layer 220 to have conformal epitaxial growth, where a thickness of the first layer 220 along the surfaces of the trench 295 (e.g., a thickness 225 and a thickness 230) may be approximately uniform (e.g., where a growth rate of the first layer 220 may be approximately uniform along the surfaces of the trench 295). Conformal epitaxial growth of the first layer 220 may cause a second layer 235 grown in the trench 295 over the first layer 220 to be formed with a void. For example, epitaxial growth of the second layer 235 may close off an opening of the trench 295 before the trench is completely filled with SiGe, leaving a void (e.g., a pocket of material other than SiGe) in the terminal portion 210. Such voids may cause significant stress relaxation in terminal portions 210 and thus reduce a compressive strain 260 applied to a substrate portion 285 by the terminal portions 210. Thus, according to the techniques described herein, the first layer 220 may be formed according to a first process that may improve the cross sectional profile of the terminal portion 210 (e.g., reducing or preventing voids, improving compressive strain 260 in substrate portions 285) by controlling a profile of the first layer 220 in the trench 295.

In some examples, the first process may form the first layer 220 while achieving a less conformal profile for the first layer 220. For example, the first process may cause a thickness 230 of the first layers 220 along the floors 275 (e.g., floor surfaces, bottoms, a cross section thickness along the Y direction in an YZ plane) of the trenches 295 to be greater than (e.g., or equal to) a thickness 225 of the first layer 220 along the sidewall 280 (e.g., sidewall surfaces, sides, a cross section thickness along the X-direction) of the trenches 295. For example, the thickness 230 may be 100% to 200% of the thickness 225. In various examples, the thickness 225 may refer to an average thickness of a portion of the first layer 220 extending from the top surface 290 to the floor 275, an average thickness of a portion of the first layer 220 extending from the top surface 290 to a floor 265 of the first layer 220 (e.g., or of any other portion of the first layer 220 in contact with the sidewall 280), a thickness of a portion of the first layer 220 in contact with a sidewall 280 of a trench 295 at a middle point (e.g., or at any other point) between the top surface 290 and the floor 275 of the trench 295, or any combination thereof. In various examples, the thickness 230 may refer to a minimum or maximum distance between the floor 265 of the first layer 220 and the floor 275 of the trench 295, an average distance between the floor 265 of the first layer 220 and the floor 275 over a section of the first layer in contact with the floor 275 and extending from the middle of the trench in the X-direction to a sidewall 280 minus the thickness 225, or any combination thereof.

In some examples, the first process may include using dichlorosilane (DCS) as a precursor in the CVD process (e.g., in addition to GeH₄, and B₂H₆, and instead of using SiH_{4,} changing a chemistry from silane (SiH4) to DCS). Additionally, or alternatively, the first process may include using a relatively higher temperature (e.g., within a range of 700-750°C, instead of 600-650°C), which may increase growth of the first layer 220 from the floor 275 relative to the growth of the first layer 220 from the sidewalls 280.

As illustrated in FIG. 2D, the second layers 235 (e.g., a second layer 235-a, a second layer 235-b) may be formed in the trenches 295 interior to each respective first layer 220 (e.g., adjacent to or directly against the first layer 220), and each second layer 235 may be partially or entirely below the top surface 290 of the substrate 205. A cross sectional profile of the second layer 235 may be based on the first layer 220. For example, the increased thickness 230 of the first layer 220 along the floor 275 may allow the second layer 235 to completely fill a remaining portion of the trench 295 before closing off the opening of the trench 295, which may reduce or remove voids within the second layer 235 and enhance the compressive strain 260 in the substrate portion 285. Additionally, the second layer 235 may be partially or entirely separated from the substrate 205 (e.g., the sidewalls 280 and the floor 275) by the first layer 220

The second layer 235 may be a third semiconductor material (e.g., SiGe) having the second concentration of germanium (e.g., that is greater than the first concentration of germanium associated with the first layer 220). In some cases, the third semiconductor material may have a p-type doping. In some examples, the second concentration of germanium (e.g., and the second layer 235) may be associated with imparting a larger portion of the compressive strain 260 on the substrate portion 285 than the first concentration (e.g., and the first layer 220). For example, the second concentration may cause a lattice constant of the third semiconductor material along the x-direction (e.g., a direction between terminal portions 210) to be more than a lattice constant of the second semiconductor material along the x-direction, causing a higher expansion of a terminal portion 210 and compression in the substrate portion 285.

In some examples, the second layers 235 may be formed using a second process, which may include epitaxial growth of SiGe. Due to the epitaxial growth (e.g., in the first process and the second process), one or more crystalline orientations between the substrate, the first layer 220, the second layer 235, or any combination thereof, may be continuous. The second process may be the same as or different from the first process. For example, the second process may use the same precursors, temperature, pressure, or any combination thereof, as the first process. Additionally, or alternatively, the second process may use SiH₄ as a precursor (e.g., instead of the DCS), a lower temperature (e.g., within a range of 600-650°C, instead of 700-750°C as in the first process), or both. Based on the less-conformal first layer 220 of SiGe, the second process may form the second layer 235 of SiGe without a void, which may increase the compressive strain 260 imparted on the substrate portion 285 by the SiGe in the first layers 220 and second layers 235, which may improve a performance of the semiconductor component.

In FIG. 2E, the third layers 240 (e.g., a third layer 240-a, a third layer 240-b) may be formed on top of the second layers 235 in the trenches 295. For example, the third layer 240 may be a fourth semiconductor material (e.g., silicon) formed over a trench 295 above the top surface 290. In some cases, the combination of a first layer 220, a second layer 235, and a third layer 240 may be a terminal portion 210 (e.g., a terminal portion).

Additionally, one or more gate portions 215 may be formed above the top surface 290 of the substrate 205 over the substrate portion 285. In some cases, the gate portion 215 may be operable to modulate a conductivity between the terminal portions 210 through the substrate portion 285. For implementations that include three or more terminal portions 210 on the substrate 205, a plurality of gate portions 215 may be formed between the terminal portions 210, and each gate portion 215 may modulate a conductivity between respective pairs of terminal portions 210. In some examples, a gate portion 215 may include a gate conductor 270, a gate dielectric 245, and one or more other portions 250, which may be associated with activating a channel that includes substrate portions 285 and at least a portion of terminal portions 210 (e.g., modulating a conductivity of the channel). Additionally, or alternatively, the third layers 240, the gate portions 215, or both, may be covered by a nitride liner 255.

Thus, in accordance with the techniques describes herein, terminal portions 210 may be formed using eSiGe with a 45-degree wafer configuration in a manner to reduce or remove voids, which may support relatively high compressive strain in substrate portions 285 to improve transistor performance.

FIGS. 3A through 3E show aspects of semiconductor components 300 (e.g., semiconductor components 300-a through 300-c) that support transistor channel compression for semiconductor devices in accordance with examples as disclosed herein. A semiconductor component 300 may be used to implement one or more components of a system 100 (e.g., as a semiconductor die, as a set of multiple semiconductor dies). For example, one or more semiconductor components 300 may be used to implement aspects of a host system 105 or portion thereof (e.g., a processor 125, a host system controller 120), or a memory system 110 or portion thereof (e.g., a memory system controller 140, a memory device 145), or a combination of aspects of a host system 105 and a memory system 110, among other implementations. Aspects of the semiconductor components 300 may be described with reference to an x-direction, a y-direction, and a z-direction of the illustrated coordinate system 301.

In various implementations, or at various stages of manufacturing, a semiconductor component 300 may refer to aspects of a semiconductor wafer, a semiconductor die, or a set of multiple (e.g., stacked, coupled) semiconductor dies, among other implementations. A semiconductor component 300 may include a substrate 205-a, upon which one or more circuit elements may be formed. For example, a substrate 205-a may include a first semiconductor material that is a basis for forming transistors, each of which may include a respective channel portion and a respective gate portion operable to modulate a conductivity of the respective channel portion. FIG. 3A may illustrate a top view of a semiconductor component 300-a (e.g., in wafer form, along the z-direction), and FIG. 3B may illustrate a cross-sectional view of a portion of a semiconductor component 300-b (e.g., in an xz-plane), both of which may illustrate features related to transistors of the respective semiconductor component 300 (e.g., terminal portions 210-a, a substrate portion 285-a as a portion of the substrate 205-a, and a gate portion 215-a operable to modulate a conductivity between terminal portions 210-a and through the substrate portion 285-a). FIGS. 2C through 2E may illustrate steps in a process of forming transistors having terminal portions 210-a (e.g., formed in trenches 295), substrate portions 285-a, and gate portions 215-a, among other aspects of a semiconductor component 300-c. Other circuit elements may be present in a semiconductor component 300 to support a given implementation, but are omitted from the illustrations.

In accordance with examples as disclosed herein, transistors of a semiconductor component 300 may include terminal portions 210-a that are formed in trenches 295 of the substrate 205-a, which may support forming substrate portions 285-a with a retained compressive stress. For example, to support at least some transistors, one or more semiconductor materials, such as one or more formulations of SiGe, may be formed in trenches 295 on either side of substrate portion(s) 285-a to form terminal portions 210-a, where such terminal portions 210-a may induce a compressive stress that enhances hole carrier mobility in the substrate portion(s) 285-a. The enhanced hole carrier mobility may significantly improve transistor performance, such as enhancing drive current, improving channel conductivity, among other benefits.

As shown in FIG. 3A, substrate portions 285-a may be configured between terminal portions 210-a in a manner that supports transistor channels being aligned along the x-direction of the coordinate system 301 (e.g., with a channel direction of one or more transistors being aligned along the x-direction), and the x-direction (e.g., an xz-plane) may be aligned relative to the substrate 205-a along an orientations of a crystalline lattice of the substrate 205-a. For example, directions relative to substrate 205-a may correspond to different crystalline orientations of the substrate 205-a (of a silicon lattice), indicated by three digits in parenthesis or chevron brackets. In the example of FIG. 3A, one or more directions may be associated with a (110) crystalline orientation, which may be some angle apart from each other (e.g., 90 degrees, more than 90 degrees, less than 90 degrees). In the illustrated arrangement of FIG. 3A, the x-direction of the coordinate system 301 (e.g., at least some transistor channels) may be aligned along a (110) crystalline orientation, and the y-direction of the coordinate system 301 may also be aligned along a (110) crystalline orientation, which may be referred to as a 0-degree orientation (e.g., a 0-degree wafer, a formation orientation with an x-direction or xz-plane oriented with a 0-degree angle relative to a (110) crystalline orientation, a formation orientation for transistor channels oriented with a 0-degree angle relative to a (110) crystalline orientation).

To support the formation of terminal portions 210-a, the sidewalls 280-a and the floor 275-a of respective trenches 295 may be configured with respective crystalline orientations that are based on the orientation of the trenches 295 relative to the lattice directions of the substrate 205-a. In some examples, a growth rate and cross sectional profile of epitaxially-formed material(s) of terminal portions 210-a may depend on the crystalline orientation of a surface within the trench 295 from which it grows. In the example of semiconductor components 300-a through 300-c, trenches 295 may be oriented on the substrate 205-a in accordance with a 0-degree wafer configuration, which may be associated with sidewalls 280-a and a floor 275-a of respective trenches 295 having different crystalline orientations (e.g., a (110) crystalline orientation and a (100) crystalline orientation, respectively). In some examples, a compressive strain 260-a on the substrate portion 285-a may increase a performance of the semiconductor components 300 more than the semiconductor components 200 based on the 0 degree wafer configuration of the trenches 295.

FIGS. 2C-2E illustrate an example of forming a semiconductor component 300-c (e.g., an eSiGe semiconductor component) in accordance with a 0-degree wafer configuration. In the example of semiconductor component 300-c, each terminal portion 210-a may include multiple semiconductor layers (e.g., epitaxial layers, three layers). For example, the semiconductor layers may include a first layer 220 (e.g., a second semiconductor material, a buffer layer, an L1 layer), a second layer 235 (e.g., a third semiconductor material, a main layer, an L2 layer), and a third layer 240 (e.g., a fourth semiconductor material, a capping layer, an L3 layer). The semiconductor layers may have different concentrations of germanium, for example. For example, a first concentration of germanium in the first layer 220 may be 20% (e.g., approximately 20%, between 10% and 30%), a second concentration of germanium in the second layer 235 may be 40% (e.g., approximately 40%, between 30% and 50%), and a third concentration of germanium in the third layer 240 may be 0% (e.g., <1% germanium concentration). Each layer may be formed (e.g., deposited, grown), for example, using CVD, which may use one or more chemical vapor precursors in conjunction with one or more other vapors to deposit the respective semiconductor material in the trenches 295.

As illustrated in FIG. 3C, one or more trenches 295 (e.g., a trench 295-c, a trench 295-d) may be formed below a top surface 290-a of the substrate 205-a. The substrate 205-a may be a first semiconductor material, and may include an n-type doping (e.g., at least in substrate portions 285-a). The trenches 295 may be formed using one or more forming techniques (e.g., chemical etching, other forming techniques). In some examples, trenches 295 may be deeper than they are wide (e.g., having a width of approximately 50 nanometers (nm) and a depth of approximately 60 nm).

Additionally, a first layer 220-c of SiGe and a first layer 220-d of SiGe may be formed in the trench 295-c and the trench 295-d, respectively. Each first layer 220 of SiGe may line the surfaces of a respective trench 295 below the top surface 290-a, and may be a second semiconductor material (e.g., SiGe, having a first concentration of germanium). In some cases, the second semiconductor material may have a p-type doping. The first layer 220 may be formed epitaxially from the sidewalls 280-a and floors 275-a of the trenches 295, which may be supported by a concentration of germanium being less than or equal to a threshold concentration (e.g., 30% concentration).

In some examples (not shown in FIG. 3C), the different crystalline orientations (e.g., (110) orientation and (100) orientation) along the sidewalls 280-a and floors 275-a of the trenches 295 (e.g., based on the 0-degree wafer configuration) may cause the first layer 220 to have nonconformal epitaxial growth, where a thickness of the first layer 220 along the surfaces of the trench 295 (e.g., a thickness 225-a and a thickness 230-a) may be nonuniform (e.g., where a growth rate of the first layer 220 may be different along different surfaces of the trench 295). For example, a thickness of the first layer 220 along the floor 275-a of the trenches 295 may be larger than (e.g., grow faster than) a thickness of the first layer 220 along the sidewalls 280-a of the trenches 295 (e.g., due to the different crystalline orientations associated with the surfaces of the trenches 295 in the 0 degree wafer configurations, not shown in FIGS. 3C through 3E). The increased epitaxial growth of the first layer 220 along the floor 275-a may cause a second layer 235 grown in the trench 295 over the first layer 220 to fill a relatively smaller portion of the trench 295 (e.g., along the z-direction, compared to the first layer 220, compared to the second layer 235 in the 45 degree wafer configuration). For example, epitaxial growth of the second layer 235 may begin at a level in the trench that is higher from the floor 275-a than in the 45 degree wafer orientation (e.g., not shown), leaving less of the second layer 235 in the terminal portion 210-a. Such decrease in the cross sectional area of the second layer 235 in terminal portions 210-a may reduce a compressive strain 260-a applied to a substrate portion 285-a by the terminal portions 210-a, as the second layer 235-a may have a higher concentration of germanium, and thus a larger lattice constant. Thus, according to the techniques described herein, the first layer 220 may be formed according to a third process that may improve the cross sectional profile of the terminal portion 210-a (e.g., increasing the cross sectional area of the second layer 235 in the terminal portion 210-a, improving the compressive strain 260-a in the substrate portion 285-a) by controlling a profile of the first layer 220 in the trenches 295.

In some examples, the third process may form the first layer 220 while achieving a relatively more-conformal profile for the first layer 220, decreasing the thickness 230-a of the first layer 220 along the floor 275, increasing a thickness 225 of the first layer 220 along the sidewalls 280, or any combination thereof. For example, the third process may cause a thickness 230-a of the first layers 220 along the floors 275-a (e.g., floor surfaces, bottoms, a cross section thickness along the y-direction from an xz-plane) of the trenches 295 to be less than (e.g., or equal to) a thickness 225-a of the first layer 220 along the sidewall 280-a (e.g., sidewall surfaces, sides, a cross section thickness along the X-direction) of the trenches 295. For example, the thickness 230-a may be 50% to 100% of the thickness 225-a. In various examples, the thickness 225-a may refer to an average thickness of a portion of the first layer 220 extending from the top surface 290-a to the floor 275-a, an average thickness of a portion of the first layer 220 extending from the top surface 290-a to a floor 265-a of the first layer 220 (e.g., or of any other portion of the first layer 220 in contact with the sidewall 280-a), a thickness of a portion of the first layer 220 in contact with a sidewall 280-a of a trench 295 at a middle point (e.g., or at any other point) between the top surface 290-a and the floor 275-a of the trench 295, or any combination thereof. In various examples, the thickness 230-a may refer to a minimum or maximum distance between the floor 265-a of the first layer 220 and the floor 275-a of the trench 295, an average distance between the floor 265-a of the first layer 220 and the floor 275-a over a section of the first layer in contact with the floor 275-a and extending from the middle of the trench in the X-direction to a sidewall 280-a minus the thickness 225-a, or any combination thereof.

In some examples, the third process may include using dichlorosilane (DCS) as a precursor in the CVD process (e.g., in addition to GeH₄, and B₂H₆, and instead of using SiH_{4,} changing a chemistry from silane (SiH4) to DCS). Additionally, or alternatively, the third process may include using a relatively higher temperature (e.g., within a range of 650-700°C, instead of 600-650°C), using a relatively higher pressure (e.g., within a range of 150-200 Torr, instead of 10–50 Torr), or both, which may decrease a growth of the first layer 220 from the floor 275-a relative to the growth of the first layer 220 from the sidewalls 280-a, or increase the growth of the first layer 220 from the sidewalls 280-a relative to the growth of the first layer 220 from the floor 275-a.

As illustrated in FIG. 3D, the second layers 235 (e.g., a second layer 235-c, a second layer 235-d) may be formed in the trenches 295 interior to each respective first layer 220 (e.g., adjacent to or directly against the first layer 220), and each second layer 235 may be partially or entirely below the top surface 290-a of the substrate 205-a. A cross sectional profile of the second layer 235 may be based on the first layer 220. For example, the decreased thickness 230-a of the first layer 220 along the floor 275-a (e.g., or increased growth of the first layer 220 along the sidewalls 280-a) may allow the second layer 235 to completely fill a relatively larger remaining portion of the trench 295, which may enhance the compressive strain 260-a in the substrate portion 285-a. Additionally, the second layer 235 may be partially or entirely separated from the substrate 205-a (e.g., the sidewalls 280-a and the floor 275-a) by the first layer 220

The second layer 235 may be a third semiconductor material (e.g., SiGe) having the second concentration of germanium. In some cases, the third semiconductor material may have a p-type doping. In some examples, the second concentration of germanium (e.g., and the second layer 235) may be associated with imparting a larger portion of the compressive strain 260-a on the substrate portion 285-a than the first concentration (e.g., and the first layer 220). For example, the second concentration may cause a lattice constant of the third semiconductor material along the x-direction (e.g., a direction between terminal portions 210-a) to be more than a lattice constant of the second semiconductor material along the x-direction, causing a higher expansion of a terminal portion 210-a and compression in the substrate portion 285-a.

In some examples, the second layers 235 may be formed using a fourth process, which may include epitaxial growth of SiGe. Due to the epitaxial growth (e.g., in the third process and the fourth process), one or more crystalline orientations between the substrate, the first layer 220, the second layer 235, or any combination thereof, may be continuous. The fourth process may be the same as or different from the third process. For example, the fourth process may use the same precursors, temperature, pressure, or any combination thereof, as the third process. Additionally, or alternatively, the fourth process may use SiH₄ as a precursor (e.g., instead of the DCS), a lower temperature (e.g., within a range of 600-650°C, instead of 650-700°C as in the third process), a lower pressure (e.g., within a range of 10–50 Torr, instead of within a range of 150-200 Torr as in the third process), or any combination thereof. Based on the more-conformal first layer 220 of SiGe, the fourth process may form the second layer 235 of SiGe with an increased cross sectional area in the terminal portions 210-a, which may increase the compressive strain 260-a imparted on the substrate portion 285-a by the SiGe in the first layers 220 and second layers 235, which may improve a performance of the semiconductor component.

In FIG. 3E, the third layers 240 (e.g., a third layer 240-c, a third layer 240-d) may be formed on top of the second layers 235 in the trenches 295. For example, the third layer 240 may be a fourth semiconductor material (e.g., silicon) formed over a trench 295 above the top surface 290-a. In some cases, the combination of a first layer 220, a second layer 235, and a third layer 240 may be a terminal portion 210-a (e.g., a terminal portion).

Additionally, one or more gate portions 215-a may be formed above the top surface 290-a of the substrate 205-a over the substrate portion 285-a. In some cases, the gate portion 215-a may be operable to modulate a conductivity between the terminal portions 210-a through the substrate portion 285-a. For implementations that include three or more terminal portions 210-a on the substrate 205-a, a plurality of gate portions 215-a may be formed between the terminal portions 210-a, and each gate portion 215-a may modulate a conductivity between respective pairs of terminal portions 210-a. In some examples, a gate portion 215-a may include a gate conductor 270-a, a gate dielectric 245-a, and one or more other portions 250-a, which may be associated with activating a channel that includes substrate portions 285-a and at least a portion of terminal portions 210-a (e.g., modulating a conductivity of the channel). Additionally, or alternatively, the third layers 240, the gate portions 215-a, or both, may be covered by a nitride liner 255-a.

Thus, in accordance with the techniques describes herein, terminal portions 210-a may be formed using eSiGe with a 0-degree wafer configuration in a manner to increase a relative portion of the second layer 235 in the terminal portions 210-a, which may support relatively high compressive strain in substrate portions 285-a to improve transistor performance.

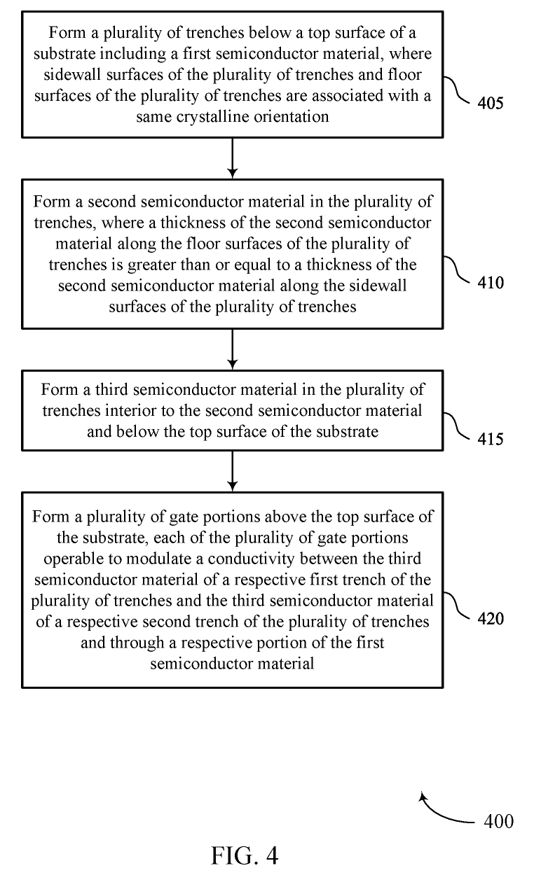

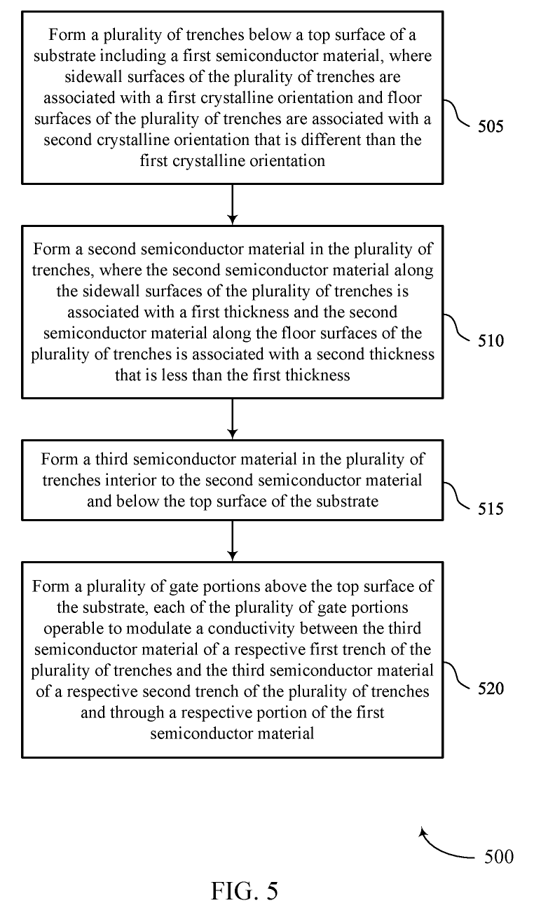

FIG. 4 shows a flowchart illustrating a method 400 that supports transistor channel compression for semiconductor devices in accordance with examples as disclosed herein. The operations of method 400 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 405, the method may include forming a plurality of trenches below a top surface of a substrate including a first semiconductor material, where sidewall surfaces of the plurality of trenches and floor surfaces of the plurality of trenches are associated with a same crystalline orientation.

At 410, the method may include forming a second semiconductor material in the plurality of trenches, where a thickness of the second semiconductor material along the floor surfaces of the plurality of trenches is greater than or equal to a thickness of the second semiconductor material along the sidewall surfaces of the plurality of trenches.

At 415, the method may include forming a third semiconductor material in the plurality of trenches interior to the second semiconductor material and below the top surface of the substrate.

At 420, the method may include forming a plurality of gate portions above the top surface of the substrate, each of the plurality of gate portions operable to modulate a conductivity between the third semiconductor material of a respective first trench of the plurality of trenches and the third semiconductor material of a respective second trench of the plurality of trenches and through a respective portion of the first semiconductor material.

In some examples, an apparatus (e.g., a manufacturing system) as described herein may perform a method or methods, such as the method 400. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for forming a plurality of trenches below a top surface of a substrate including a first semiconductor material, where sidewall surfaces of the plurality of trenches and floor surfaces of the plurality of trenches are associated with a same crystalline orientation; forming a second semiconductor material in the plurality of trenches, where a thickness of the second semiconductor material along the floor surfaces of the plurality of trenches is greater than or equal to a thickness of the second semiconductor material along the sidewall surfaces of the plurality of trenches; forming a third semiconductor material in the plurality of trenches interior to the second semiconductor material and below the top surface of the substrate; and forming a plurality of gate portions above the top surface of the substrate, each of the plurality of gate portions operable to modulate a conductivity between the third semiconductor material of a respective first trench of the plurality of trenches and the third semiconductor material of a respective second trench of the plurality of trenches and through a respective portion of the first semiconductor material.

Aspect 2: The method or apparatus of aspect 1, where the same crystalline orientation is associated with a (100) crystalline orientation.

Aspect 3: The method or apparatus of any of aspects 1 through 2, where the first semiconductor material includes silicon; the second semiconductor material includes silicon and a first concentration of germanium that is within a range of 10% to 30% germanium; and the third semiconductor material includes silicon and a second concentration of germanium, greater than the first concentration, that is within a range of 30% to 50% germanium.

Aspect 4: The method or apparatus of any of aspects 1 through 3, where the second semiconductor material and the third semiconductor material are formed epitaxially with the first semiconductor material.

FIG. 5 shows a flowchart illustrating a method 500 that supports transistor channel compression for semiconductor devices in accordance with examples as disclosed herein. The operations of method 500 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 505, the method may include forming a plurality of trenches below a top surface of a substrate including a first semiconductor material, where sidewall surfaces of the plurality of trenches are associated with a first crystalline orientation and floor surfaces of the plurality of trenches are associated with a second crystalline orientation that is different than the first crystalline orientation.

At 510, the method may include forming a second semiconductor material in the plurality of trenches, where the second semiconductor material along the sidewall surfaces of the plurality of trenches is associated with a first thickness and the second semiconductor material along the floor surfaces of the plurality of trenches is associated with a second thickness that is less than the first thickness.

At 515, the method may include forming a third semiconductor material in the plurality of trenches interior to the second semiconductor material and below the top surface of the substrate.

At 520, the method may include forming a plurality of gate portions above the top surface of the substrate, each of the plurality of gate portions operable to modulate a conductivity between the third semiconductor material of a respective first trench of the plurality of trenches and the third semiconductor material of a respective second trench of the plurality of trenches and through a respective portion of the first semiconductor material.

In some examples, an apparatus (e.g., a manufacturing system) as described herein may perform a method or methods, such as the method 1000. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 5: A method or apparatus including operations, features, circuitry, logic, means, or instructions, or any combination thereof for forming a plurality of trenches below a top surface of a substrate including a first semiconductor material, where sidewall surfaces of the plurality of trenches are associated with a first crystalline orientation and floor surfaces of the plurality of trenches are associated with a second crystalline orientation that is different than the first crystalline orientation; forming a second semiconductor material in the plurality of trenches, where the second semiconductor material along the sidewall surfaces of the plurality of trenches is associated with a first thickness and the second semiconductor material along the floor surfaces of the plurality of trenches is associated with a second thickness that is less than the first thickness; forming a third semiconductor material in the plurality of trenches interior to the second semiconductor material and below the top surface of the substrate; and forming a plurality of gate portions above the top surface of the substrate, each of the plurality of gate portions operable to modulate a conductivity between the third semiconductor material of a respective first trench of the plurality of trenches and the third semiconductor material of a respective second trench of the plurality of trenches and through a respective portion of the first semiconductor material.

Aspect 6: The method or apparatus of aspect 5, where the first crystalline orientation is associated with a (110) orientation and the second crystalline orientation is associated with a (100) orientation.

Aspect 7: The method or apparatus of any of aspects 5 through 6, where the first semiconductor material includes silicon; the second semiconductor material includes silicon and a first concentration of germanium that is within a range of 10% to 30% germanium; and the third semiconductor material includes silicon and a second concentration of germanium, greater than the first concentration, that is within a range of 30% to 50% germanium.

Aspect 8: The method or apparatus of any of aspects 5 through 7, where the second semiconductor material and the third semiconductor material are formed epitaxially with the first semiconductor material.

It should be noted that the aspects described herein describe possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A semiconductor device, comprising:
a substrate comprising a first semiconductor material, the substrate comprising a top surface and a plurality of trenches below the top surface;
a plurality of terminal portions, each of the plurality of terminal portions comprising a respective layer of a second semiconductor material lining a respective trench of the plurality of trenches and comprising a respective portion of a third semiconductor material interior to the lining of the second semiconductor material in the respective trench and below the top surface of the substrate; and
a plurality of gate portions above the top surface of the substrate, each of the plurality of gate portions operable to modulate a conductivity between a respective first terminal portion of the plurality of terminal portions and a respective second terminal portion of the plurality of terminal portions and through a respective portion of the first semiconductor material.

2. The semiconductor device of claim 1, wherein for each of the plurality of terminal portions, sidewall surfaces of the respective trench and a floor surface of the respective trench are associated with a same crystalline orientation.

3. The semiconductor device of claim 2, wherein for each of the plurality of terminal portions, a thickness of the second semiconductor material along the floor surface of the respective trench is greater than or equal to a thickness of the second semiconductor material along the sidewall surfaces of the respective trench.

4. The semiconductor device of claim 2, wherein the same crystalline orientation is associated with a (100) crystalline orientation.

5. The semiconductor device of claim 1, wherein, for each of the plurality of terminal portions:
sidewall surfaces of the respective trench are associated with a first crystalline orientation; and
a floor surface of the respective trench is associated with a second crystalline orientation that is different than the first crystalline orientation.

6. The semiconductor device of claim 5, wherein:
the first crystalline orientation is associated with a (110) orientation; and
the second crystalline orientation is associated with a (100) orientation.

7. The semiconductor device of claim 5, wherein, for each of the plurality of terminal portions:
the second semiconductor material along the sidewall surfaces of the respective trench is associated with a first thickness; and
the second semiconductor material along the floor surface of the respective trench is associated with a second thickness that is less than the first thickness.

8. The semiconductor device of claim 1, wherein:
the first semiconductor material comprises silicon;
the second semiconductor material comprises silicon and a first concentration of germanium; and
the third semiconductor material comprises silicon and a second concentration of germanium that is greater than the first concentration.

9. The semiconductor device of claim 8, wherein:
the first concentration is within a range of 10% to 30% germanium; and
the second concentration is within a range of 30% to 50% germanium.

10. The semiconductor device of claim 1, wherein each of the plurality of terminal portions further comprises a respective portion of a fourth semiconductor material over the respective trench above the top surface of the substrate.

11. The semiconductor device of claim 1 wherein a lattice constant of the first semiconductor material along a direction between terminal portions is less than a lattice constant of the third semiconductor material along the direction between terminal portions.

12. The semiconductor device of claim 1, wherein one or more crystalline orientations are continuous between the first semiconductor material, the second semiconductor material, and the third semiconductor material.

13. The semiconductor device of claim 1, wherein, for each of the plurality of gate portions:
the respective portion of the first semiconductor material comprises an n-type doping; and
the second semiconductor material, the third semiconductor material, or both of the respective first terminal portion and the respective second terminal portion comprise a p-type doping.

14. A method of manufacturing a semiconductor device, comprising:
forming a plurality of trenches below a top surface of a substrate comprising a first semiconductor material, wherein sidewall surfaces of the plurality of trenches and floor surfaces of the plurality of trenches are associated with a same crystalline orientation;
forming a second semiconductor material in the plurality of trenches, wherein a thickness of the second semiconductor material along the floor surfaces of the plurality of trenches is greater than or equal to a thickness of the second semiconductor material along the sidewall surfaces of the plurality of trenches;
forming a third semiconductor material in the plurality of trenches interior to the second semiconductor material and below the top surface of the substrate; and
forming a plurality of gate portions above the top surface of the substrate, each of the plurality of gate portions operable to modulate a conductivity between the third semiconductor material of a respective first trench of the plurality of trenches and the third semiconductor material of a respective second trench of the plurality of trenches and through a respective portion of the first semiconductor material.

15. The method of claim 14, wherein the same crystalline orientation is associated with a (100) crystalline orientation.

16. The method of claim 14, wherein:
the first semiconductor material comprises silicon;
the second semiconductor material comprises silicon and a first concentration of germanium that is within a range of 10% to 30% germanium; and
the third semiconductor material comprises silicon and a second concentration of germanium, greater than the first concentration, that is within a range of 30% to 50% germanium.

17. The method of claim 14, wherein the second semiconductor material and the third semiconductor material are formed epitaxially with the first semiconductor material.

18. A method of manufacturing a semiconductor device, comprising:
forming a plurality of trenches below a top surface of a substrate comprising a first semiconductor material, wherein sidewall surfaces of the plurality of trenches are associated with a first crystalline orientation and floor surfaces of the plurality of trenches are associated with a second crystalline orientation that is different than the first crystalline orientation;
forming a second semiconductor material in the plurality of trenches, wherein the second semiconductor material along the sidewall surfaces of the plurality of trenches is associated with a first thickness and the second semiconductor material along the floor surfaces of the plurality of trenches is associated with a second thickness that is less than the first thickness;
forming a third semiconductor material in the plurality of trenches interior to the second semiconductor material and below the top surface of the substrate; and
forming a plurality of gate portions above the top surface of the substrate, each of the plurality of gate portions operable to modulate a conductivity between the third semiconductor material of a respective first trench of the plurality of trenches and the third semiconductor material of a respective second trench of the plurality of trenches and through a respective portion of the first semiconductor material.

19. The method of claim 18, wherein:
the first crystalline orientation is associated with a (110) orientation; and
the second crystalline orientation is associated with a (100) orientation.

20. The method of claim 18, wherein:
the first semiconductor material comprises silicon;
the second semiconductor material comprises silicon and a first concentration of germanium that is within a range of 10% to 30% germanium; and
the third semiconductor material comprises silicon and a second concentration of germanium, greater than the first concentration, that is within a range of 30% to 50% germanium.
